(19) United States
(12) Patent Application Publication
(10) Pub. No.: US 2010/0078311 A1
(43) Pub. Date: Apr. 1, 2010

(54) Aluminum Floride Thin Film Deposition Method

(76) Inventors: Cheng-Chung LEE, Pin-Cheng (TW); Bo-Huei Liao, Sinshe Township (TW); Ming-Chung Liu, Chung-Li (TW)

Correspondence Address: TROXELL LAW OFFICE PLLC, Suite 1404, 5205 Leesburg Pike, Falls Church, VA, 22041, US

(21) Appl. No.: 12/239,762

(22) Filed: Sep. 27, 2008

(51) Int. Cl. C23C 14/46

(52) U.S. Cl. 204/192.11

(57) ABSTRACT

An aluminum fluoride thin film deposition method includes the steps of (a) putting a substrate and a pure aluminum target in a plasma sputtering system, (b) applying argon plasma to the plasma sputtering system to remove impurities from the aluminum target, (c) applying CF₄ gas, which is stable at room temperature under the atmospheric pressure, to the plasma sputtering system to bombard the aluminum target with energetic ions and to have aluminum atoms be ejected from the aluminum target and fluorinated so that a thin-film coating of aluminum fluoride is deposited on the surface of the substrate.

### BACKGROUND OF THE INVENTION

1. Field of the Invention

The present invention relates to the deposition of an aluminum fluoride thin film on a substrate and more particularly, to such an aluminum fluoride thin film deposition method that utilizes pure aluminum as the start material.

2. Description of the Related Art

Following the market trend of integrated circuits toward small size and high density characteristics, lithography plays a major role in semiconductor manufacturing process. Photolithography is a process used in micro-fabrication to selectively remove parts of a thin film. It uses light to transfer a geometric pattern from a photomask to a photoresist on the substrate. A series of chemical treatments then engraves the exposure pattern into the material underneath the photoresist. Photolithography can use visible light, near ultraviolet light, mid ultraviolet light, deep ultraviolet light, vacuum ultraviolet light, extreme ultraviolet light or X-ray. Among these light sources, deep ultraviolet light is much more important in present-day lithography process. The conventional coating techniques commonly utilize high purity of aluminum fluoride as the start material for thermal evaporation. However, such an evaporation has the drawback of low packing density, showing a significant influence to the environment. When a sputtering technique is employed to increase the packing density, it relatively causes an increase in absorption in deep ultraviolet region. Fluorine gas may be added to improve the stoichiometry of the thin films during sputtering. However, this is dangerous, because fluorine gas is detrimental to both human bodies and experimental instruments. Further, high purity of aluminum fluoride is quite expensive. The use of high purity of aluminum fluoride greatly increases the coating cost.

Therefore, it is desirable to provide a safer coating technique that lowers the cost of coating and reduces the absorption of aluminum fluoride thin films in deep ultraviolet region.

### SUMMARY OF THE INVENTION

The present invention has been accomplished under the circumstances in view. It is the main object of the present invention to provide an aluminum fluoride thin film deposition method, which utilizes pure aluminum as the start material and dissociates CF₄ gas for depositing an aluminum fluoride thin film through a plasma etching technique, assuring high level of safety and greatly lowering the cost of coating.

To achieve this and other objects of the present invention, the aluminum fluoride thin film deposition method comprises the steps of (a) putting a substrate and a pure aluminum target as the start material in a plasma sputtering system, (b) applying argon plasma to the plasma sputtering system to remove impurities from the aluminum target, (c) applying CF₄ gas, which is stable at room temperature under the atmospheric pressure, to the plasma sputtering system to bombard the aluminum target with energetic ions and to have aluminum atoms be ejected from the aluminum target and fluorinated so that a thin-film coating of aluminum fluoride is deposited on the surface of the substrate.

### DETAILED DESCRIPTION OF THE PREFERRED EMBODIMENT

An aluminum fluoride thin film deposition method in accordance with the present invention is to coat a substrate with an aluminum fluoride thin film. The method comprises in proper order the step of putting a substrate and a pure aluminum target (purity larger than 99.99%) in a plasma sputtering system, the step of applying argon plasma to the plasma sputtering system to remove impurities from the aluminum target, the step of applying CF₄ gas, which is stable at room temperature under the atmospheric pressure, to the plasma sputtering system to bombard the aluminum target with energetic ions and to have aluminum atoms be ejected from the aluminum target and fluorinated, causing formation of a thin-film coating of aluminum fluoride on the surface of the substrate.

During coating, oxygen may be added to accelerate the dissociation of CF₄ gas into energetic fluoride atoms or ions, enhancing fluorination of aluminum atoms and, at the same time to have the carbon that is dissociated from CF₄ gas be oxidized into CO₂ and then guided out of the reaction chamber of the plasma sputtering system, reducing the risk of contamination of the deposited aluminum fluoride coating and the aluminum target with carbon and lowering the absorption of the thin film and increasing the sputtering rate.

Unlike conventional techniques, the invention utilizes the start material of inexpensive pure aluminum to substitute for costly aluminum fluoride compound. Then, energetic fluoride atoms or ions dissociated from a safer plasma system enable aluminum atoms be quickly fluorinated into an aluminum fluoride thin film on the prepared substrate. An aluminum fluoride thin film deposited according to the present invention has the advantage of high packing density like conventional sputtering techniques and low absorption loss as good as a thermal evaporation process.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. An aluminum fluoride thin film deposition method, comprising the step of guiding CF₄ gas that is stable at room temperature under the atmospheric pressure to a plasma sputtering system to bombard an aluminum target with energetic ions and to have aluminum atoms be ejected from said aluminum target and fluorinated, causing deposition of an aluminum fluoride thin film.

2. The aluminum fluoride thin film deposition method as claimed in claim 1, wherein said aluminum fluoride thin film is deposited on the surface of said substrate.

3. The aluminum fluoride thin film deposition method as claimed in claim 1, wherein said CF₄ gas is dissociated by means of plasma etching.

4. The aluminum fluoride thin film deposition method as claimed in claim 3, further comprising the step of adding O₂ gas to said plasma sputtering system to enhance fluorination of aluminum atoms and to have the carbon that is dissociated from CF₄ gas be oxidized into CO₂ and then guided out of said plasma sputtering system.

5. The aluminum fluoride thin film deposition method as claimed in claim 4, wherein the carbon that is dissociated from CF₄ gas is oxidized into CO₂ and then guided out of said plasma sputtering system.

6. The aluminum fluoride thin film deposition method as claimed in claim 1, wherein said aluminum target has a purity of at least 99.99%.
